(19) United States
(12) Patent Application Publication
(10) Pub. No.: US 2005/0196680 A1
(43) Pub. Date: Sep. 8, 2005

(54) Multi-image reticles

(76) Inventors: Eric Bouche, San Jose, CA (US); Scott Corboy, Singapore (SG); Wong Chee Yoong Lawrence, Singapore (SG)

Correspondence Address: CONLEY ROSE, P.C., P. O. BOX 3267, HOUSTON, TX, 77253-3267, US

(21) Appl. No.: 10/503,167

(22) PCT Filed: Oct. 30, 2003
(86) PCT No.: PCT/SG03/00254

§ 371 Date: Jul. 30, 2004

(30) Foreign Application Priority Data
Nov. 1, 2002 (WO) PCT/SG02/00258

(51) Int. Cl. G03C 5/00; G03F 9/00

(52) U.S. Cl. 430/5; 430/322

(57) ABSTRACT

A reticle 100 includes two or more image patterns for different layers of an integrated circuit, each one in a separate image field 110-120. These image layers are used in the production of the same integrated circuit. By placing multiple image layers on the same reticle, fewer reticles need to be produced and a prototype circuit can then be made more cheaply. Likewise the reduced set of reticles can be used where there is a limited run of circuits. If any or all reticle layers need to be replaced, then the replacement set is also cheaper.

### FIELD OF THE INVENTION

The present invention relates to reticles and to the production of reticles for use in lithography. In particular, it relates to such reticles and the production of reticles that are useful in prototyping.

### BACKGROUND

Lithography involves the making of a copy of a pattern in a photosensitive photoresist coating on a substrate, usually a semiconductor substrate. Different areas of the coating are irradiated according to the pattern in a reticle or mask. The irradiated areas are then dissolved in a solvent during further processing; leaving only the non irradiated areas of the coating behind. Integrated circuits are built up by repeating this process a number of times using different patterns. A typical integrated circuit manufacturing process may involve up to thirty different patterns being added in this manner. With increasing complexity in circuits, this number is likely to increase.

A typical known reticle 10 is shown in FIG. 1. The reticle is a glass plate covered with a chrome layer 12. This chrome layer is removed in certain areas and during lithographic processing, light passes through these areas of the reticle. The pattern area 14 is in the middle of the reticle and includes an image pattern 16 (consisting of areas of removed and remaining chrome) to be copied into the photoresist coating on a wafer. In this instance, the pattern 16 is repeated six times in a two-by-three matrix. The size of reticle and pattern can vary and therefore the number of repeating patterns will change accordingly. Usually one seeks to have the largest number of repeats of the pattern possible, to reduce the number of times a wafer has to be moved for one wafer to be irradiated over its entire surface.

The pattern area 14 includes a test frame 18 surrounding the repeated pattern. This is made up of two horizontal scribelanes 20, one above and one below the pattern area and two vertical scribelanes 22, one on each side of the pattern area 14. Each horizontal scribelane 20 consists of various wafer making test structures: Critical Dimension (CD) and overlay test structures (OCM boxes) with thickness test structures strung out between them. There are usually about thirty such structures extending from one side of the pattern area 14 to the other. The patterns left by these test structures on a wafer are checked after the layer has been processed to confirm that everything has been made correctly. If there are any problems with Critical Dimensions (CD) or alignment (Overlay), the wafers are reworked for that layer by removing the resist and trying again. If the thickness structures are out of specification by being too thin, then extra film is deposited on the wafer to recover the situation. If the thickness structures are out of specification by being too thick, then the excess is polished or etched off. Each vertical scribelane 22 consists of electrical test areas. These are provided so that the electrical properties of the resulting etched layer can be tested. However, for these test areas the tests have to wait until the end of the process, when the complete test structures have been constructed down the sides of the completed integrated circuits.

The chrome area around the test frame 18 extends a width of at least 3.5 mm in the horizontal directions and 5 mm in the vertical direction, these minimum margins being known as the chrome border 24. The purpose of this is to make sure that unwanted light does not pass through the reticle through other gaps in the chrome to contaminate and ruin the wafer. Outside the chrome border 24, there is a bar code 26 to allow the reticle to be identified automatically and a written identifier 28 to allow easy human identification. Finally there are two positioning markers 30 to allow the reticle to be positioned accurately during use. In each case the bar code 26, identifier 28 and markers 30 are provided by chrome being removed.

Whilst a standard reticle as shown in FIG. 1 contains a single pattern repeated several times, for prototyping purposes it has also been known to have two different image areas on a reticle, suitably separated, for use in producing different circuits, possibly for different customers. Even within these image areas it is also known to have image fields for different circuits, which are put down at the same time on the same wafer. These are known as Multi-Product Wafers (MPW).

U.S. Pat. No. 5,705,299, issued on 6 Jan. 1998, to Tew et al., describes a reticle with several different image areas on it. These image areas are all used to stitch a single layer pattern together, when the layer pattern is larger than the reticle field.

U.S. Pat. No. 6,368,754, issued on 9 Apr. 2002, to Imai, describes a reticle with two different image areas on it. The two image areas are again used on different areas of the same layer pattern.

FIG. 2 is a block diagram showing a typical flow relating to the design of a set of reticles. Firstly, a customer 40 determines that he requires a particular circuit to be made in silicon. This circuit is designed in a design house 42 that is either internal or external to the customer 40. The design of the circuit is then forwarded to a chip-finishing department 44 as GDS design data. The GDS data contains details of every component of the circuit, including the position co-ordinates for each component. In chip finishing 44, the reticles that are required for the production of each layer that makes up the circuit are designed. Typically there are between five to thirty of these. The information defining these reticles is passed as MEBES, reticle writing data, to a mask shop 46 where the various Reticle designs are then etched into chrome on reticle glass. Finally, the reticles are used in a fabrication plant 48 to produce integrated circuits according to the design, on semiconductor wafers.

Before an extended production run can be initiated, it is necessary to test integrated circuits that are produced. If there is a problem with the circuit design, then usually one or more reticles will need to be redesigned and replaced. At the worst, the whole set of reticles will need replacing. Typically, 50% of the prototyping runs of any set of reticles fail in at least one respect. If this requires a completely new set of thirty of so reticles being produced, then this may typically cost around US$350,000. It is therefore quite expensive to produce an initial set of reticles and then to redesign and reproduce various of these, if not all of these, until a working design is achieved.

U.S. Pat. No. 4,758,863, issued on 19 Jul. 1988, to Nikkel, describes using a reticle on which is a series of different mask patterns, all for use in the same lithographic process. The different mask patterns are rotated relative to each other, at 180 degrees when there are just two different patterns or at 90 degrees when there are four of them. The reticle is rotated from one image pattern to the next, in layer order until all have been used.

Japanese Patent Application Publication No. 02/2,556, published on 8 Jan. 1990, in the name of Sharp Corporation describes a stepper reticle with a number of different image patterns positioned sequentially side by side. Individual patterns are exposed sequentially, while the other patterns are masked.

Japanese Patent Application Publication No. 04/404,453, published on 27 Oct. 1992, in the name of Fujitsu Ltd describes a stepper reticle with four different image patterns, two for each of two different semiconductor devices, positioned side by side. Individual patterns are exposed, while the other patterns are masked.

### SUMMARY OF THE INVENTION

According to one aspect of the present invention, there is provided a reticle for use in the production of an integrated circuit. The reticle has thereon different image patterns of different grades. The different image patterns are for creating patterns for different layers, during the production of the same integrated circuit.

According to a second aspect of the present invention, there is provided a reticle for use in the production of an integrated circuit, comprising a plurality of different image patterns. The different image patterns are for creating patterns for different layers and are for use at different times during the production of the same integrated circuit. The reticle lacks a second image pattern for use, between a first image pattern which is on the reticle and a third image pattern which is on the reticle, during the production of the same integrated circuit.

According to another aspect of the present invention, there is provided a reticle set for producing an integrated circuit, the set comprising a plurality of reticles, each as defined above.

According to again another aspect of the present invention, there is provided a reticle set for use in producing an integrated circuit, the set comprising a plurality of reticles. Individual reticles of the plurality of reticles comprise a plurality of different image patterns thereon. The different image patterns of the plurality of reticles are for creating patterns for different layers and are for use at different times during the production of the same integrated circuit. The different image patterns of the plurality of reticles are for use in a predetermined order during the production of the integrated circuit. In the predetermined order a first image pattern which is on a first one of the plurality of reticles, is used before a second image pattern which is on a second one of the plurality of reticles, which second pattern is used before a third image pattern which is on the first one of the plurality of reticles.

According to a further aspect of the present invention, there is provided a method of producing a reticle for use in the production of an integrated circuit using a plurality of different image patterns in a predetermined order. The method comprising scribing the reticle with different image patterns of different grades. The different image patterns are for creating patterns for different layers during the production of the same integrated circuit.

According to again another aspect of the present invention, there is provided a method of producing a reticle for use in the production of an integrated circuit using a plurality of different image patterns in a predetermined order, the method comprising scribing the reticle with a plurality of different image patterns. The image patterns are scribed such that the different image patterns are for creating patterns for different layers and are for use at different times during the production of the same integrated circuit. The image patterns are scribed such that the reticle lacks an image pattern for use, in the predetermined order, between a first image pattern and a second image pattern during the production of the same integrated circuit.

According to again another aspect of the present invention, there is provided a method of producing a reticle set for use in producing an integrated circuit, said set comprising a plurality of reticles. The method comprising scribing said plurality of reticles. Individual reticles of said plurality of reticles comprise a plurality of different image patterns thereon. The different image patterns of the plurality of reticles are for creating patterns for different layers in creating different layers during the production of the same integrated circuit. At least one reticle comprises image patterns of different grades.

According to a further aspect of the present invention, there is provided a method of producing a reticle set for use in producing an integrated circuit, the set comprising a plurality of reticles, the method comprising scribing the plurality of reticles. The image patterns are scribed such that individual reticles of the plurality of reticles comprise a plurality of different image patterns thereon. The image patterns are scribed such that the different image patterns of the plurality of reticles are for creating patterns for different layers and are for use at different times during the production of the same integrated circuit. The image patterns are scribed such that the different image patterns of the plurality of reticles are for use in a predetermined order during the production of the integrated circuit. The image patterns are scribed such that, in the predetermined order, a first image pattern which is on a first one of the plurality of reticles, is used before a second image pattern which is on a second one of the plurality of reticles, which second pattern is used before a third image pattern which is on the first one of the plurality of reticles.

According to yet a further aspect of the present invention, there is provided a method for use in determining a reticle recipe, the recipe being for use in producing a reticle set, where individual reticles of said reticle set comprise a plurality of different image patterns thereon, the reticle set being for use in the production of an integrated circuit using a plurality of different image patterns. The method comprises deciding which image patterns are to be included on a same reticle of the reticle set. When making this decision image patterns of different grades are permitted to be included on a same reticle.

According to another aspect of the present invention, there is provided a method for use in determining a reticle recipe, the recipe being for use in producing a reticle set, where individual reticles of said reticle set comprise a plurality of different image patterns thereon, the reticle set being for use in the production of an integrated circuit using a plurality of different image patterns in a predetermined order. The method comprises: deciding which image patterns are to be included on a same reticle of the reticle set. When making this decision first and third image patterns are permitted to be placed on a same reticle whilst a second image pattern which, within said predetermined order is between the first and third image patterns, is not to be placed on said same reticle.

According to yet another aspect of the present invention, there is provided a method for use in determining a reticle recipe, the recipe being for use in producing a reticle set, where individual reticles of the reticle set comprise a plurality of different image patterns thereon, the reticle set being for use in the production of an integrated circuit using a plurality of different image patterns in a predetermined order. The method comprises deciding which image patterns are to be put on a same reticle of the reticle set, whilst not permitting line and space image layer patterns to be on a same reticle of the reticle set as contact image layer patterns.

According to yet another aspect of the present invention, there is provided software operable according to either of the above two methods for use in determining a reticle recipe. The software may, for instance, be stored on a suitable medium, such as a CD-ROM or floppy disc or downloaded via the Internet.

According to a further aspect of the present invention, there is provided a method of making an integrated circuit using a plurality of reticles, wherein individual reticles of the plurality of reticles comprise a plurality of different image patterns thereon. The method comprises imaging a first layer pattern of an integrated circuit on an area of a substrate, after imaging the first layer pattern, imaging a second layer pattern of the integrated circuit on the area of the substrate and after imaging the second layer pattern, imaging a third layer pattern of the integrated circuit on the area of the substrate. Imaging the first layer pattern uses a first image pattern which is on a first one of the plurality of reticles. Imaging the second layer pattern uses a second image pattern which is on a second one of the plurality of reticles. Imaging the third layer pattern uses a third image pattern which is on the first one of the plurality of reticles.

According to another further aspect of the present invention, there is provided a reticle for use in the production of an integrated circuit, having at least first and second different image patterns thereon, for use in creating patterns for different layers and at different times during the production of the same integrated circuit.

According to an even further aspect of the present invention, there is provided a method of producing a production integrated circuit. This comprises: providing an integrated circuit using a plurality of reticles or a reticle set of one of or produced using one of the above aspects, as a prototype integrated circuit, making a further set of reticles, based on the reticles used to produce the prototype integrated circuit; and using the further set of reticles to produce the production integrated circuit, each reticle of the further set of reticles being used only once in producing the production integrated circuit.

Further aspects of the invention include a reticle produced using a method of one or more of the above-mentioned aspects, a reticle set produced using a method of one or more of the above-mentioned aspects and an integrated circuit produced using a method of one or more of the above-mentioned aspects.

Thus a reticle of at least one aspect of the invention includes two or more image patterns for different layers of an integrated circuit, each one usually in a separate image field. These image patterns are used in the production of the same integrated circuit. The image patterns are used in a predetermined order. Between at least two of the image patterns on the reticle, an image pattern on a different reticle is used, within that predetermined order. By placing multiple image patterns on the same reticle, fewer reticles need to be produced and a prototype circuit can then be made more cheaply. Likewise the reduced set of reticles can be used where there is a limited run of circuits. If any or all reticle layers need to be replaced, then the replacement set is also cheaper.

### DESCRIPTION OF THE DRAWINGS

The present invention is further described by way of non-limitative example with reference to the accompanying drawings, in which:

FIG. 1 shows a typical known reticle;

FIG. 2 is a block diagram representing the flow of orders and data in reticle design;

FIG. 3 shows a reticle according to an embodiment of the present invention;

FIG. 4 is an enlarged view of an area A within FIG. 3;

FIG. 5 is an enlarged view of a first area within FIG. 4; and

FIG. 6 is an enlarged view of a second area within FIG. 4.

### DETAILED DESCRIPTION

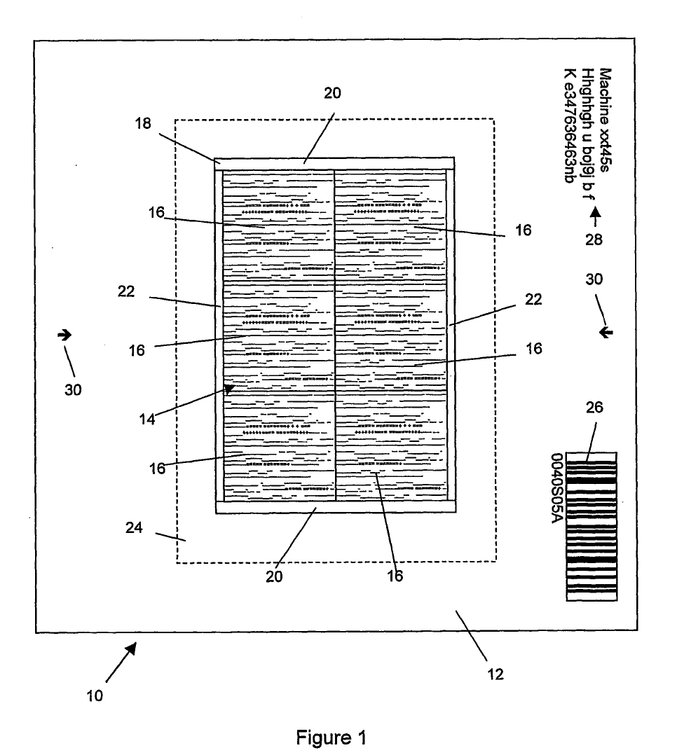

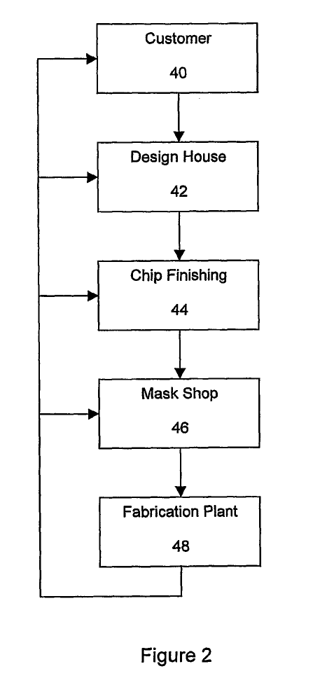

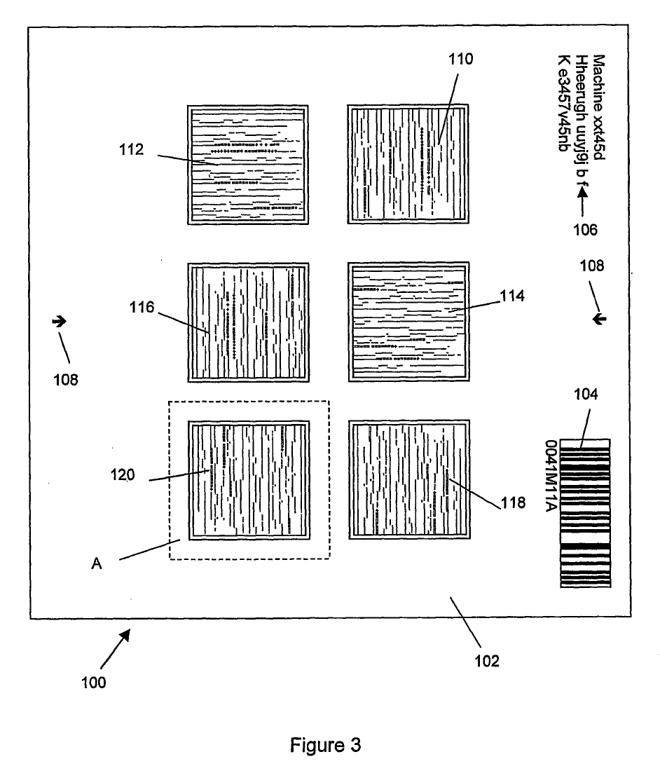

FIG. 3 shows a reticle according to an embodiment of the present invention. It shares many of the features of the prior art shown in FIG. 1 but differs significantly in that the six patterns shown are all different, being used for different layers of the same circuit.

In FIG. 3, the reticle 100 is a glass plate covered with a chrome layer 102. A bar code 104 allows automatic identification, whilst a written identifier 106 allows human identification. Positioning markers 108 allow the reticle to be positioned accurately during use.

There are six distinct image fields 110-120 each containing a different image pattern for a different layer and thereby for use at different times. In this instance, image field 110 contains line layer 1 pattern, image field 112 contains line layer 2 pattern, image field 114 contains line layer 4 pattern, image field 116 contains line layer 3 pattern, image field 118 contains line layer 5 pattern and image field 120 contains line layer 7 pattern (Reticle 1 of Table 1—see later). Between each image field, there is sufficient space for the chrome border requirements. In this embodiment the image fields are orientated in the same direction, although in other embodiments they may be rotated relative to each other if desired.

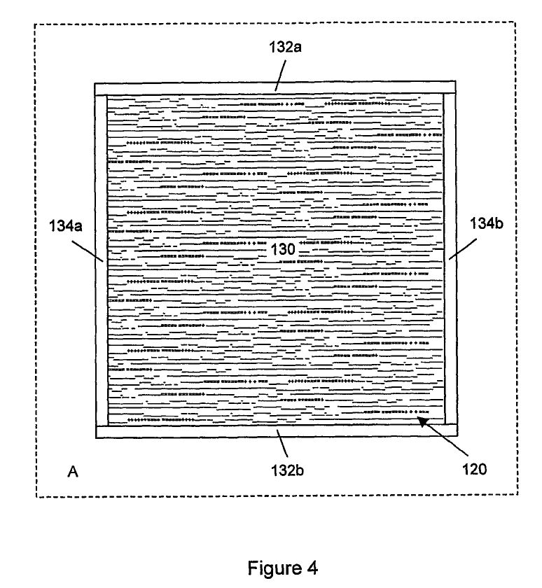

Area A, encompassing image field 120, is shown in more detail in FIG. 4. The general structure of the contents of each image field is the same, although the specific details of each image pattern and test frame will differ.

FIG. 4 shows area A of FIG. 3 in greater detail. Image field 120 is made up of a lithographic pattern 130 with a test frame of two horizontal scribelanes 132a, 132b and two vertical scribelanes 134a, 134b (although in this embodiment the right-hand vertical scribelane 134b is empty). Thus relevant test structures for each pattern surround each pattern individually, rather then a single set of test structures surrounding all six patterns, as in FIG. 1.

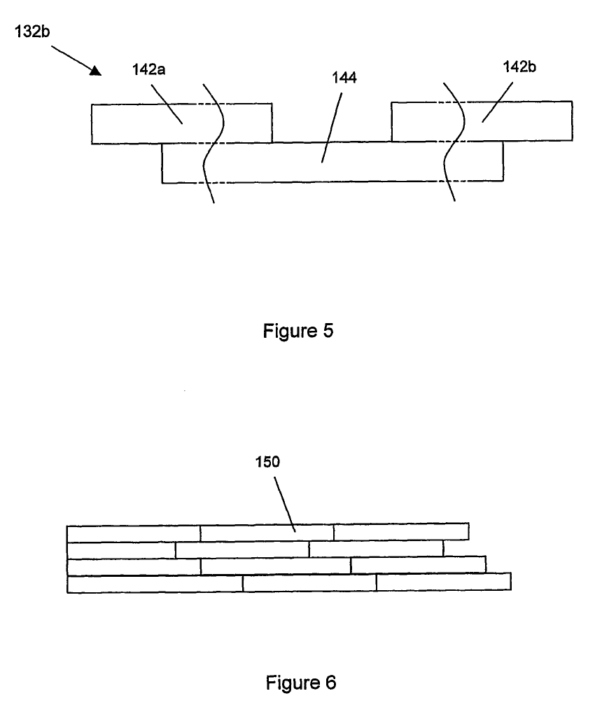

FIG. 5 schematically shows the lower horizontal scribelane 132b in greater detail. Both horizontal scribelanes 132a, 132b contain the same number of test structures as in the prior art. However, rather then being strung out horizontally, the structures in the present invention may be bricked out, extending across the surface of the reticle in the vertical direction. Thus, whereas the overlay and critical dimension structures in the prior art have the thickness boxes strung out between them horizontally, in this instance, the overlay and critical dimension structures (OCM boxes) 142a, 142b lie above the thickness structure 144 in the vertical direction across the surface of the reticle. There are two sets of overlay and critical dimension structures 142a, 142b, extending horizontally above the thickness structure across the reticle, which are separated slightly from each other in the horizontal direction. The overlay and critical dimension structures 142a, 142b and thickness structure 144 extend in two single rows, although, if necessary, there can be more than one row of each in a single scribelane.

The scribelane of FIG. 5 is the lower horizontal scribelane 132b. The upper one 132a is a mirror image of the lower one, reflected across a horizontal axis. Thus in the upper scribelane 132a, the two overlay and critical dimension structures are below the thickness structure. The two thickness structures, of the upper and lower horizontal scribelanes between them make up a single row of test structures when put down onto a wafer.

Typically, a horizontal scribelane has a minimum length of 16 mm and a depth of 100 μm (microns). In the presence instance, the scribelane is 6 mm long, with the thickness of 200 μm (microns). Because the vertical depth is relatively small, it does not matter if the test structures are stacked in several layers across the surface. The length of the thickness box structure is 5.5 mm and combined length of the two OCM structures on a single line of the scribelane is 5 mm, so there is almost complete overlap. However, the OCM boxes 142a, 142b are positioned as near to the image field corners as possible, thereby overhanging the ends of the thickness box structure 144. Thus the gap between the two OCM boxes 142a, 142b is more than 0.5 mm. Around 5 or 6 mm is the normal minimum length of horizontal scribelane, since that is the minimum length of a typical thickness box. However, it can be shorter, if the constituent boxes of the test structure allow this. If the image pattern 130 itself is not as wide as the minimum width of the horizontal scribelane, then the pattern can be repeated within the same image field 120, as can the image patterns in the same various other image fields, as in the prior art, with a single test frame surrounding each set of repeated patterns.

FIG. 6 shows a schematic block diagram for the left-hand vertical scribelane 134a. As with the prior art, this consists of a number of electrical test areas. Again, because the length of the scribelane available to the test structures is shorter then in the prior art, the electrical test structures 150 are stacked outwards, this time in the horizontal direction of the reticle. Although in this embodiment all the electrical test areas are in this left-hand vertical scribelane 134a, these structures could be shared with or wholly within the right-hand vertical scribelane 134b.

The scribelanes in the present invention are organised differently and positioned differently from in the prior art. However, different positioning and differing lengths of scribelane already exist in the prior art and thus the scribelanes of the present invention can easily be tested without needing to adjust any machines except for the programming of the specific test. Scribelanes of the present invention are not limited to the vertical and horizontal scribelanes as shown. For instance, they can swap positions or be in different formats.

The number of image fields possible on one reticle is determined by calculating the size of each image field by adding the size of the engineering test structures to that of the chip (and scaling accordingly, where there is a size reduction during exposure) and comparing this with the maximum available reticle area, based on the exposure tool and the necessary borders around each field to prevent nuisance patterns.

The reticle of FIG. 3 contains patterns for six different layers, all to be used on the same circuit. Ideally all the patterns on a single reticle would be used consecutively, so that for a thirty layers process, there would be just five reticles with the first six processes on reticle 1, the second six on reticle 2 etc. Unfortunately, this is not always possible for various reasons, in which case it becomes necessary to group layers into reticle recipes, according to those patterns that can be placed on the same reticle.

TABLE 1
Table 1 is a table showing the recipes for a set of six reticles, having twenty-nine
different image patterns between them (image 1 on reticle 2 is used twice).

| | | Prev | Proposed | Reticle | Reticle | CD | Order |
|---|---|---|---|---|---|---|---|
| Image | Layer | Grade | Grade | Type | Material | Target (4×) | of use |
| Reticle | Barcode: | | | | | | |
| 1 | 0041M11A | | | | | | |
| 1 | Line Layer 2 | E | G | Line/Space | Binary | 1.728 | 2 |
| 2 | Line Layer 4 | E | G | Line/Space | Binary | 3.600 | 4 |
| 3 | Line Layer 1 | F | G | Line/Space | Binary | 1.008 | 1 |
| 4 | Line Layer 7 | G | G | Line/Space | Binary | 0.720 | 7 |
| 5 | Line Layer 3 | E | G | Line/Space | Binary | 3.600 | 3 |
| 6 | Line Layer 5 | D | G | Line/Space | Binary | 1.728 | 5 |
| Reticle | Barcode: | | | | | | |
| 2 | 0041M12A | | | | | | |
| 1 | Line Layer 6 | E | E | Line/Space | Binary | 1.728 | 6 & 14 |
| 2 | Line Layer 10 | E | E | Line/Space | Binary | 1.728 | 10 |
| 3 | Line Layer 11 | E | E | Line/Space | Binary | 1.728 | 11 |
| 4 | Line Layer 13 | E | E | Line/Space | Binary | 1.728 | 13 |
| 5 | Line Layer 12 | E | E | Line/Space | Binary | 1.728 | 12 |
| 6 | Line Layer 14 | D | E | Line/Space | Binary | 1.728 | 15 |
| Reticle | Barcode: | | | | | | |
| 3 | 0041M13A | | | | | | |
| 1 | Line Layer 28 | B | D | Line/Space | Binary | NA | 29 |
| 2 | Line Layer 8 | D | D | Line/Space | Binary | 1.728 | 8 |
| 3 | Line Layer 9 | D | D | Line/Space | Binary | 1.728 | 9 |
| 4 | Line Layer 29 | B | D | Line/Space | Binary | 3.600 | 30 |
| Reticle | Barcode: | | | | | | |
| 4 | 0041M14A | | | | | | |
| 1 | PSM Layer 1 | G | G | Contact | Phase Shift | 1.044 | 16 |
| | | | | | (PSM) | | |
| 2 | PSM Layer 2 | G | G | Contact | Phase Shift | 1.044 | 17 |
| | | | | | (PSM) | | |
| Reticle | Barcode: | | | | | | |
| 5 | 0041M15A | | | | | | |
| 1 | Line Layer 17 | F | F | Line/Space | Binary | 1.152 | 18 |
| 2 | Line Layer 19 | F | F | Line/Space | Binary | 1.152 | 20 |
| 3 | Line Layer 21 | F | F | Line/Space | Binary | 1.152 | 22 |
| 4 | Line Layer 23 | F | F | Line/Space | Binary | 1.152 | 24 |
| 5 | Line Layer 25 | F | F | Line/Space | Binary | 2.304 | 26 |
| 6 | Line Layer 27 | F | F | Line/Space | Binary | 2.304 | 28 |
| Reticle | Barcode: | | | | | | |
| 6 | 0041M16A | | | | | | |
| 1 | Contact Layer 1 | F | F | Contact | Binary | 1.080 | 19 |
| 2 | Contact layer 2 | F | F | Contact | Binary | 1.080 | 21 |
| 3 | Contact Layer 3 | F | F | Contact | Binary | 1.080 | 23 |
| 4 | Contact Layer 4 | F | F | Contact | Binary | 1.080 | 25 |
| 5 | Contact Layer 5 | F | F | Contact | Binary | 2.160 | 27 |

Table 1 includes various components:
“Bar code” indicates the identifier for the reticle. Reticle naming is configured to fit within fabrication tool protocols to allow transparent wafer processing
“Image” indicates the positioning of the relevant image field on the reticle. In this embodiment, image 1 is top right, image 2 is top left, image 3 is middle right, image 4 is middle left, image 5 is bottom right and image 6 is bottom left. The ordered sequence of positions is thus between consecutive images and rows.
“Layer” identifies the type of layer that is to be formed.
“Prev grade” indicates the grade of reticle normally used for an individual layer. Reticles can generally be graded from grade A (lowest grade) to grade G (highest grade). “Prev grade” in effect indicates the grade of the layer.
“New grade” indicates the grade of reticle that is to be used for that layer, the same grade to be used for the whole of any one reticle and the grade having to be suitable for all the image layers present on that reticle.
“CD Target (4×)” indicates the critical dimensions of the features on the reticle, which in this example are 4× the target critical dimensions to be achieved in the resist during lithography.
“Order of use” indicates the order of use of the different image layers within the whole process of using the reticle set to make an integrated circuit. Thus, for example, Reticle 2 is used for the sixth process, before Reticle 1 is finished with. Further, even within a reticle, the image layers do not necessarily appear in the order in which they are to be used (see Reticles 1 and 2). A program deciding where to place the image layers may decide otherwise.

These reticles of Table 1 are for use with 180 nm technology. They were formulated based on the rules and preferences below. The compatibility of the layers that are put on one reticle is checked to allow transparent manufacturing of the reticles by the mask shop.

Rule 1—Line and spaces cannot be mixed with contact layers.
Every pattern can be generally categorised into either providing lines and spaces or providing contacts. These cannot be mixed on the same reticle because the reticle manufacturing process is different for the different types of process. Thus in Table 1, all the image layers of reticles 1, 2, 3 and 5 are defined as line and space layers, whilst all those in reticles 4 and 6 are defined as contact layers.

Rule 2—Do not downgrade a layer, always put it on the same or a better grade of reticle.
Different layers require different grades of reticle, in terms of mean to target (how close to the designed size the actual size on the reticle is), uniformity (what the CD variation is across the plate, typically sampled at >20 sites), registration (how well centred the pattern is, with respect to the alignment marks on the reticle) and defects (how many defects there are on the reticle, and what the sizes of these defects are). Whilst an image layer pattern can still work when put on a better grade of reticle, it cannot work, or not as well if on a lesser grade of reticle than is normally required. Individual reticles themselves are generally only of one grade.

Rule 3—Reticle types cannot be mixed. It is not possible to mix phase shift modulation (PSM) reticles with binary reticles.
Thus Reticle 4 in Table 1 only contains two image layers, because they alone in example, as it only has two image fields on it, it is classified as a small field size reticle.

Rule 7 Try, where possible to put most critical (higher grade) layers towards the centre of a reticle.
If a reticle contains layers of different grades, less critical, lower grade layers being present with more critical higher grade layers, to reduce the number of reticles used, the higher grade layers are better off nearer the centre of the reticle. This is because mask writing tools tend to write more accurately near the centre of a reticle. If all the layers are of the same grade, then usually some will have to be further from the centre than others.

Thus the example reticle set of Table 1 has six reticles, of which three have six layers, one has five layers, one has four layers and one has two layers. Use of the present invention, may quite often lead to reticle sets with at least three reticles having different numbers of image layers or patterns thereon.

Reticle recipes can be determined according to the invention using software running on a standard desktop computer. The software is written to incorporate the above rules, with the preference rules absent, present and individually optional or present and obligatory.

Whilst the rules in the cases above are particularly relevant to 180 nm technology, they are not limited thereto. Many of the rules still apply to smaller and larger technologies, although for larger technologies, such as 2 μm (micron) technologies, PSM is not used and therefore Rule 3 becomes redundant. Others of the rules might also become redundant in particular situations and likewise new rules may be added also. The present invention is useful for almost all sizes of technology, whether 2 μm (micron) or 180 nm or even smaller technologies. Likewise, it can be used with electromagnetic radiation lithography of various wavelengths.

Multi-layer reticles of the present invention can be designed, produced and used using existing systems. In terms of what is required of the circuit by the customer, that is not changed at all, nor does the circuit design. The only extra steps occur in chip finishing, because it is now necessary to determine reticle recipes for distributing the image layers and manipulate incoming GDS data. All the engineering structures that are needed for wafer manufacturing have to be Included in every image field in each reticle. The mask shop works in the same way, in that it produces the mask according to the in put data, although the mask contains six different patterns, as opposed to one pattern repeated six times. Finally, the fabrication plant behaves in the same way, except that the exposure tool has to be able to select different ones of the image areas at different stages of the process. Further, a smaller area on any wafer is exposed in any one step, so that it takes roughly four times as long to produce a completed wafer of integrated circuits. This is because the number of circuits per area of wafer tends to be smaller (due to the additional spacing between each one). However, the actual processing time for creating a prototyping wafer or a limited run of integrated circuits is generally not critical.

In this manner, a complete set of reticles for a process can be built for much less than it previously cost, even allowing for the additional work in deciding on the reticle recipes. For example, the cost may be one quarter or less of the cost of a full set of prior art reticles.

The present invention is ideally suited for prototyping, whereby once the reticle set has been tested and approved, a normal full set of thirty reticles or so may then be produced to the same design (but with one repeating pattern per reticle). This is necessary because for large production runs, the multi-layer reticles would be too slow. However, the multi-layer reticles can be used for limited production runs quite readily. The product is not in any way inferior to that produced by a repeated pattern reticle set, and can be tested just as completely and readily.

As well as the multi-layer reticle sets themselves being an improvement, they also give rise to an improved business approach. Parties wishing to have reticle sets made up for them can have the option of a normal full reticle set or a multi-layer reticle sets according to their own situation and whether the design has already been proven. The decision could even be just a tick box option on an order form.

Whilst the invention has been embodied with reticles having two, four and six image patterns, the present invention will also work with other numbers, for instance, three or five patterns or even more than six.

In this description, the terms horizontal and vertical and upper and lower, etc appear. This is for ease of understanding, based on the orientation of the figures and is not intended to be limiting unless that would be understood from the context. Thus other embodiments of the invention could readily have the different features rotated 90 degrees relative to what is shown (or other angular amounts if appropriate). The orientation is generally not important.

It would be quite clear to the person skilled in the art that various modifications can be made to the present invention without departing from the scope of the invention as described and claimed.

1. A reticle for use in the production of an integrated circuit, having thereon different image patterns of different grades, for creating patterns for different layers during the production of the same integrated circuit.

2. A reticle for use in the production of an integrated circuit, comprising a plurality of different image patterns, wherein
the different image patterns are for creating patterns for different layers and are for use at different times during the production of the same integrated circuit; and
said reticle lacks a second image pattern for use, between a first image pattern which is on the reticle and a third image pattern which is on the reticle, during the production of the same integrated circuit.

3. A reticle according to claim 2, wherein the plurality of different image patterns comprise image patterns of different grades.

4. A reticle according to claim 1, wherein the higher grade image patterns are at least as near to the centre of the reticle as are the lower grade image patterns.

5. A reticle according to claim 4, wherein the higher grade image patterns are nearer to the centre of the reticle than are the lower grade image patterns.

6. A reticle according to claim 1, wherein the reticle comprises a plurality of each of said different image patterns.

7. A reticle according to claim 1, further comprising at least one scribelane for each different image pattern, the scribelanes including a thickness box structure in the length wise direction of the scribelane.

8. A reticle according to claim 7, wherein at least one critical dimension structure overlaps the thickness box structure in the length wise directions of the scribelanes.

9. A reticle according to claim 7, wherein at least one overlay structure overlaps the thickness box structure in the length wise directions of the scribelanes.

10. A reticle according to claim 1, wherein:
the different image patterns have an order of use in producing a circuit;
the reticle includes an ordered sequence of image areas between consecutive image areas and rows; and
the order of the different image patterns within the sequence of image areas is different from the order of use of the image patterns relative to each other.

11. A reticle according to claim 1, wherein the reticle is of a single grade.

12. A reticle for use in the production of an integrated circuit, having at least first and second different image patterns thereon, for use in creating patterns for different layers and at different times during the production of the same integrated circuit.

13. A reticle set for use in producing an integrated circuit, said set comprising a plurality of reticles, wherein
individual reticles of said plurality of reticles comprise a plurality of different image patterns;
the different image patterns of individual reticles of said plurality of reticles are for creating patterns for different layers and are for use at different times during the production of the same integrated circuit; and
a first reticle of said plurality of reticles comprises a first image pattern and a third image pattern and lacks a second image pattern for use between said first and second image patterns during the production of the same integrated circuit.

14. A reticle set according to claim 13, wherein
the different image patterns of the plurality of reticles are for use in a predetermined order during the production of said integrated circuit; and
in said predetermined order, a first image pattern which is on a first one of said plurality of reticles, is used before a second image pattern which is on a second one of said plurality of reticles, which second pattern is used before a third image pattern which is on said first one of said plurality of reticles.

15. A reticle set for use in producing an integrated circuit, said set comprising a plurality of reticles; wherein
individual reticles of said plurality of reticles comprise a plurality of different image patterns thereon;
the different image patterns of the plurality of reticles are for creating patterns for different layers and are for use at different times during the production of the same integrated circuit;
the different image patterns of the plurality of reticles are for use in a predetermined order during the production of said integrated circuit; and
in said predetermined order, a first image pattern which is on a first one of said plurality of reticles is used before a second image pattern which is on a second one of said plurality of reticles, which second pattern is used before a third image pattern which is on said first one of said plurality of reticles.

16. A reticle set according to claim 13, wherein different reticles of said set have different numbers of image patterns thereon.

17. A reticle set according to claim 16, comprising at least three reticles with different numbers of image patterns thereon.

18. A method of producing a reticle for use in the production of an integrated circuit using a plurality of different image patterns in a predetermined order, the method comprising scribing said reticle with different image patterns of different grades, such that the different image are for creating patterns for different layers during the production of the same integrated circuit.

19. A method of producing a reticle for use in the production of an integrated circuit using a plurality of different image patterns in a predetermined order, the method comprising scribing said reticle with a plurality of different image patterns such that:
the different image patterns are for creating patterns for different layers and are for use at different times during the production of the same integrated circuit; and
said reticle lacks an image pattern for use, in said predetermined order, between a first image pattern and a second image pattern during the production of the same integrated circuit.

20. A method of producing a reticle set for use in producing an integrated circuit, said set comprising a plurality of reticles, the method comprising scribing said plurality of reticles such that:
individual reticles of said plurality of reticles comprise a plurality of different image patterns thereon;
the different image patterns of the plurality of reticles are for creating patterns for different layers during the production of the same integrated circuit; and
at least one reticle comprises image patterns of different grades.

21. A method of producing a reticle set for use in producing an integrated circuit, said set comprising a plurality of reticles, the method comprising scribing said plurality of reticles such that:
individual reticles of said plurality of reticles comprise a plurality of different image patterns thereon;
the different image patterns of the plurality of reticles are for creating patterns for different layers and are for use at different times during the production of the same integrated circuit;
the different image patterns of the plurality of reticles are for use in a predetermined order during the production of said integrated circuit; and
in said predetermined order, a first image pattern which is on a first one of said plurality of reticles is used before a second image pattern which is on a second one of said plurality of reticles, which second pattern is used before a third image pattern which is on said first one of said plurality of reticles.

22. A method for use in determining a reticle recipe, the recipe being for use in producing a reticle set, where individual reticles of said reticle set comprise a plurality of different image patterns thereon, the reticle set being for use in the production of an integrated circuit using a plurality of different image patterns, the method comprising: deciding which image patterns are to be included on a same reticle of the reticle set and, in doing so, permitting image patterns of different grades to be included on a same reticle.

23. A method for use in determining a reticle recipe, the recipe being for use in producing a reticle set, where individual reticles of said reticle set comprise a plurality of different image patterns thereon, the reticle set being for use in the production of an integrated circuit using a plurality of different image pattern layers in a predetermined order, the method comprising: deciding which image patterns are to be included on a same reticle of the reticle set and, in doing so, permitting first and third image patterns to be placed on a same reticle whilst a second image pattern which, within said predetermined order is between the first and third image patterns, is not to be placed on said same reticle.

24. A method according to claim 23, further comprising, in deciding which image patterns are to be included on a same reticle of the reticle set, permitting image patterns of different grades to be included on a same reticle.

25. A method according to claim 22, further comprising determining the orders of the image patterns on the reticles, such that, on a reticle that is to include image patterns of different grades, the higher grade image patterns are determined to be at least as near to the centre of the reticle as are the lower grade image patterns.

26. A method according to claim 25, wherein the higher grade image patterns are determined to be nearer to the centre of the reticle than are the lower grade image patterns.

27. A method according to claim 23, further comprising not allowing line and space image layer patterns to be on a same reticle of the reticle set as contact image layer patterns.

28. A method according to claim 23, further comprising not allowing phase shift modulation layer patterns on a same reticle of the reticle set as binary layer patterns.

29. A method according to claim 23, further comprising choosing the grade of a reticle of the reticle set to be the minimum grade necessary or preferred according to the image patterns to be placed thereon.

30. Computer software for determining a reticle recipe for use in producing a reticle set, where individual reticles of said reticle set comprise a plurality of different image patterns thereon, the reticle set being for use in the production of an integrated circuit using a plurality of different image patterns, the software being operable in accordance with a method comprising: deciding which image patterns are to be included on a same reticle of the reticle set and, in doing so, permitting image patterns of different grades to be included on a same reticle.

31. A method of producing an integrated circuit using a plurality of reticles, wherein individual reticles of said plurality of reticles comprise a plurality of different image patterns thereon, the method comprising:
imaging a first layer pattern of an integrated circuit on an area of a substrate using a first image pattern which is on a first one of said plurality of reticles;
after imaging the first pattern, imaging a second layer pattern of the integrated circuit on the area of the substrate using a second image pattern which is on a second one of said plurality of reticles; and
after imaging the second layer pattern, imaging a third layer pattern of the integrated circuit on the area of the substrate using a third image pattern which is on said first one of said plurality of reticles.

32. A method of producing a production integrated circuit comprising the steps of:
producing a prototype integrated circuit using a first reticle set;
making a further set of reticles, based on the first reticle; and
using said further set of reticles to produce said production integrated circuit, individual reticles of the further set of reticles being used only once in producing said production integrated circuit; wherein
the first reticle set comprises a plurality of prototype reticles, with individual reticles of said plurality of reticles comprising a plurality of different image patterns thereon; and
producing the prototype integrated circuit comprises:
imaging a first layer pattern of an integrated circuit on an area of a substrate using a first image pattern which is on a first one of said plurality of prototype reticles;
after imaging the first layer pattern, imaging a second layer pattern of the integrated circuit on the area of the substrate using a second image pattern which is on a second one of said plurality of prototype reticles; and
after imaging the second layer pattern, imaging a third layer pattern of the integrated circuit on the area of the substrate using a third image pattern which is on said first one of said plurality of prototype reticles.
